(19) United States
(12) Patent Application Publication
(10) Pub. No.: US 2005/0167802 A1
(43) Pub. Date: Aug. 4, 2005

(54) Semiconductor device

(75) Inventors: Naohiko Hirano, Okazaki-city (JP); Kuniaki Mamitsu, Okazaki-city (JP)

Correspondence Address: POSZ LAW GROUP, PLC, 12040 SOUTH LAKES DRIVE, SUITE 101, RESTON, VA, 20191, US

(73) Assignee: DENSO CORPORATION

(21) Appl. No.: 11/019,242

(22) Filed: Dec. 23, 2004

(30) Foreign Application Priority Data
Jan. 30, 2004 (JP) 2004-23000
Oct. 4, 2004 (JP) 2004-291397

(51) Int. Cl. H01L 23/02

(52) U.S. Cl. 257/678

(57) ABSTRACT

A semiconductor device includes first and second semiconductor elements, a first metal body attached to a first side of the semiconductor elements by a first solder portion, a second metal body attached to a second side of the semiconductor elements with a second solder portion, and a resin mold sealing the semiconductor elements, the first metal body and the second metal body by encapsulating them. In the semiconductor device having the second side as an element disposition surface, strain measurement caused by heat stress is maximum at the first solder portion among soldering portions of the semiconductor elements.

### CROSS REFERENCE TO RELATED APPLICATIONS

This application is based upon, claims the benefit of priority of, and incorporates by reference the contents of, Japanese Patent Application No. 2004-23000 filed on Jan. 30, 2004 and Japanese Patent Application No. 2004-291397 filed on Oct. 4, 2004.

### FIELD OF THE INVENTION

The present invention relates generally to a semiconductor device molded with a resin and more particularly to a semiconductor device having metal bodies attached to opposite sides of a semiconductor element with a solder.

### BACKGROUND OF THE INVENTION

A conventional semiconductor device generally includes a semiconductor element, a first electrode composed of a first metal body attached on a first side of the semiconductor element via a first solder, and a second electrode composed of a second metal body attached on a second side, which is opposite to the first side, via a second solder. The first and second electrodes have heat radiating properties. A resin mold seals all of the semiconductor elements, the first metal body, and the second metal body. Such a semiconductor device is disclosed, for example, in Japanese Patent Application No. 2003-110064, the contents of which are incorporated herein by reference.

However, in the conventional semiconductor device, an increased heat flux in the semiconductor element causes an excessive high temperature, which causes cracks in the soldering portion.

The crack in the solder interrupts a heat dissipation path, and thus the radiation characteristic of the device deteriorates.

Because the semiconductor device described above has many soldering portions, prioritizing soldering portions to decide which soldering portion to be broken becomes complex.

In view of the above-described problem, it is an object of the present invention to provide a resin molded semiconductor device having the soldered first metal body on the first side of the semiconductor element and the soldered second metal body on the second side, in which deterioration of heat dissipation characteristics is suppressed when breakage is caused by heat stress in soldering portions.

### SUMMARY OF THE INVENTION

In the present disclosure, a semiconductor device structure in which a second side of the semiconductor element is dedicated for element disposition and regarded as ‘an element disposition surface,’ and the first side of the semiconductor element does not have an element on it will be discussed.

A lifetime of the soldering portion is generally defined by a breakage rate of the solder, and widening of the crack by heat stress increases a thermal resistance. However, in this case, the first side of the semiconductor element having no semiconductor element on it is affected the least by the increased thermal resistance in comparison with the second surface. The semiconductor device of the present disclosure takes advantage of this characteristic.

According to a first aspect, the semiconductor device includes semiconductor elements, a first metal body serving as an electrode and a radiator attached to a first side of the semiconductor elements with a first solder, a second metal body also serving as an electrode and a radiator attached to a second side (opposite to the first side) of the semiconductor elements with a second solder, and a resin mold sealing the semiconductor elements, the first metal body and the second metal body by encapsulating them. Accordingly, strain measurement caused by heat stress is at a maximum at the first solder among soldering portions of the semiconductor elements in the semiconductor device having the second side as an element disposition surface.

That is, because the strain measurement caused by heat stress is at a maximum at the first solder, the first solder will be the first one to be broken when heat stress further concentrates on that particular portion.

Accordingly, the semiconductor device, in which the soldered first metal body on the first side of the semiconductor element and the soldered second metal body on the second side, is devised so that deterioration of heat dissipation characteristics is suppressed when breakage is caused by heat stress in the soldering portions.

According to a second aspect, the semiconductor device is characterized by the first solder covering an entire surface of the first side of the semiconductor elements, and the second solder covering a part of the second side of the semiconductor elements with a predetermined distance between the periphery of the solder and the edge of the second side.

According to the present structure of the semiconductor device in which the edge of the solder resides inside the edge of the second side of the semiconductor element with a certain distance, the strain on the solder caused by heat stress measured is smaller in comparison to the structure in which the solder covers the entire surface of second side of the semiconductor element as shown in FIG. 2.

Therefore, the strain measurement of the second solder by heat stress on the second side of the semiconductor elements becomes smaller than that of the first solder by heat stress on the first side of the semiconductor elements.

That is, the strain measurement of the first solder by heat stress can be appropriately maximized in the present structure.

According to a third aspect, the semiconductor device of the first or second aspects is characterized by having plural semiconductor elements of different planar sizes in which a larger semiconductor element has a thinner thickness.

The strain measurement of the solder on the semiconductor element by heat stress becomes larger when the thickness of the semiconductor element is greater.

More particularly, the thinner the thickness of the semiconductor element is, the smaller the strain at the soldering portion becomes, especially in the semiconductor element having the larger planar size.

According to a fourth aspect, the semiconductor device of the third aspect is further characterized by semiconductor elements comprising an IGBT element and an FWD element, wherein the FWD element has a planar size smaller than that of the IGBT element.

According to a fifth aspect, the semiconductor device of any one of the first to fourth aspects is further characterized by the thickness of the solder, wherein the first solder is thinner than the second solder.

According to the inventors, it is clarified that the thinner the thickness of the solder is, the larger the strain of the solder caused by heat stress becomes.

That is, the strain measurement of the second solder becomes smaller than that of the first solder when thickness of the first solder is thinner than that of the second solder.

Therefore, the strain measurement of the first solder by heat stress can appropriately be maximized.

According to a sixth aspect, the semiconductor device of the first or second aspects, is further characterized by the plural semiconductor elements of different thickness being disposed on the same plane between the single first metal body and the single second metal body opposing to the first metal body, and the elements bound by the first metal body and the second metal body.

According to the semiconductor device of the first or second aspects, as mentioned in the sixth aspect, each of the plurality of semiconductor elements of have a different thickness (t1, t1′). Further, the plurality of semiconductor elements are disposed on the same plane in parallel between the first metal body and the second metal body.

However, when the semiconductor elements are different in thickness (t1, t1′) and are sandwiched by the metal bodies, the outer surfaces of the metal bodies, that is, the radiating surface of the first metal body and the radiating surface of the second metal body have a tendency to become tilted, and no longer be in parallel.

A semiconductor element sandwiched by radiating metal bodies on the obverse/first sides, for example, is cooled by contacting cooling members on the metal bodies. In this case, heat dissipation efficiency is decreased if both radiating surfaces of the metal bodies are not disposed in parallel resulting in the loss of full contact with the cooling members.

According to a seventh aspect, if the radiating surface of the first metal body and the radiating surface of the second metal body are exposed from the resin mold in the semiconductor device of the sixth aspect, the loss of contact between the cooling members and the radiating surfaces constitutes a serious problem.

Further, if the metal bodies are not arranged in parallel, the resin mold is prone to cover the radiating surfaces of the metal bodies because of a gap between the radiating surfaces and the resin mold.

The inventors determined through intense study the present approach for securing the parallel arrangement of the radiating surfaces of the metal bodies and preventing the deterioration of heat dissipation efficiency in case of breakage of soldering portions caused by heat stress.

According to an eighth aspect, the semiconductor device of the sixth or seventh aspect is further characterized by the following points.

For each of the semiconductor elements, a different third metal body is disposed between the second solder on the semiconductor elements and the single second metal body.

Each of the semiconductor elements and the third metal bodies are attached with the second solder, and each of the third metal bodies and the second single metal bodies are attached with the third solder.

The thickness (t4, t4′) of each of the third metal bodies is different so that the radiating surface of the single first metal body and the radiating surface of the second metal body are disposed in parallel.

In the semiconductor device characterized by the points described above, the thickness of each of the third metal bodies disposed between each of the semiconductor elements and the second metal body, is adjusted to absorb the difference of the thickness (t1, t1′) of each the semiconductor elements.

Therefore, a parallel arrangement of the radiating surface of the first metal body and the radiating surface of the second metal body can be secured while at the same time achieving the primary objective of suppressing deterioration of heat dissipation characteristics when breakage is caused by heat stress.

The semiconductor device with efficient heat dissipation can thus be provided because of the full contact between the cooling members and each radiating surfaces and the prevention of resin burr formation on the radiating surface.

Furthermore, the semiconductor device of the sixth or seventh aspect, as mentioned in the ninth aspects, is characterized by the following points.

For each of the semiconductor elements, a different third metal body is disposed between the second solder on the semiconductor elements and the single second metal body.

Each of the semiconductor elements and the third metal body are attached with the second solder, and each of the third metal bodies and the single second metal body are attached with the third solder.

The thickness (t5, t5′) of each of the third solder portions is adjusted (differentiated) so that the radiating surface of the single first metal body and the radiating surface of the second metal body are disposed in parallel.

In the semiconductor device characterized by the points described above, the third solder between the third metal body and the semiconductor elements together with the third metal body absorb the difference of thickness (t1, t1′) of the semiconductor elements.

Therefore, the parallel arrangement of the radiating surface of the first metal body and the radiating surface of the second metal body as well as the primary objective can be secured.

The semiconductor device having efficient heat dissipation can thus be provided because of the full contact between the cooling members and each radiating surface and the prevention of resin burr formation on the radiating surface.

Further, the semiconductor device of the sixth or seventh aspect, as mentioned with respect to the tenth aspect, is further characterized by the single second metal body having a concave/convex portion on the semiconductor elements facing side. The concave/convex portion permits arrangement of the radiating surface of the single first metal body and the radiating surface of the single second metal body in parallel.

Therefore, for each of the semiconductor elements with different thickness (t1, t1′), a concave/convex portion is disposed on the second metal body, and the concave/convex portion absorbs the difference of thickness between each semiconductor element.

As a result, the present invention can secure the parallel arrangement of the radiating surface of the first metal body and the radiating surface of the second metal body in addition to the primary objective. Further, the semiconductor device with efficient heat dissipation can thus be provided because of the full contact between the cooling members and each radiating surface and the prevention of resin burr formation on the radiating surface.

According to an eleventh aspect, the semiconductor device according to any one of sixth to tenth aspects is further characterized by the first solder and the second solder containing a metal powder for defining a height of the solder.

The metal powder makes it easier to adjust the height of the first and second solder and thus the parallel arrangement of the radiating surface of the first metal body and the radiating surface of the second metal body can preferably be secured.

According to a twelfth aspect, the semiconductor device of any one of the sixth to eleventh aspects, is further characterized by the plural semiconductor elements of different thickness (t1, t1′), that is, the relatively thin IGBT element and the FWD element being thicker than the IGBT element.

### BRIEF DESCRIPTION OF THE DRAWINGS

The above and other objects, features and advantages of the present invention will become more apparent from the following detailed description made with reference to the accompanying drawings:

FIG. 1 is a schematical cross-sectional view of the semiconductor device according to a preferred embodiment;

FIG. 2 is a diagram depicting the relationship between the distance d and the equivalent plastic strain value ε at the edge of the first and second solder portions;

FIG. 3 is a schematical cross-sectional view of the model used in FIG. 2;

FIGS. 4A-4B are schematical cross-sectional views of a semiconductor device according to first and second modifications; and

FIG. 5 is a schematical cross-sectional view of the first and second solders according to a third modification.

### DETAILED DESCRIPTION OF THE PREFERRED EMBODIMENT

Each of the preferred embodiments of the present invention will be described with reference to the drawings. In each of the drawings, the same or equivalent portions have the same numerals for the purpose of simplicity of description.

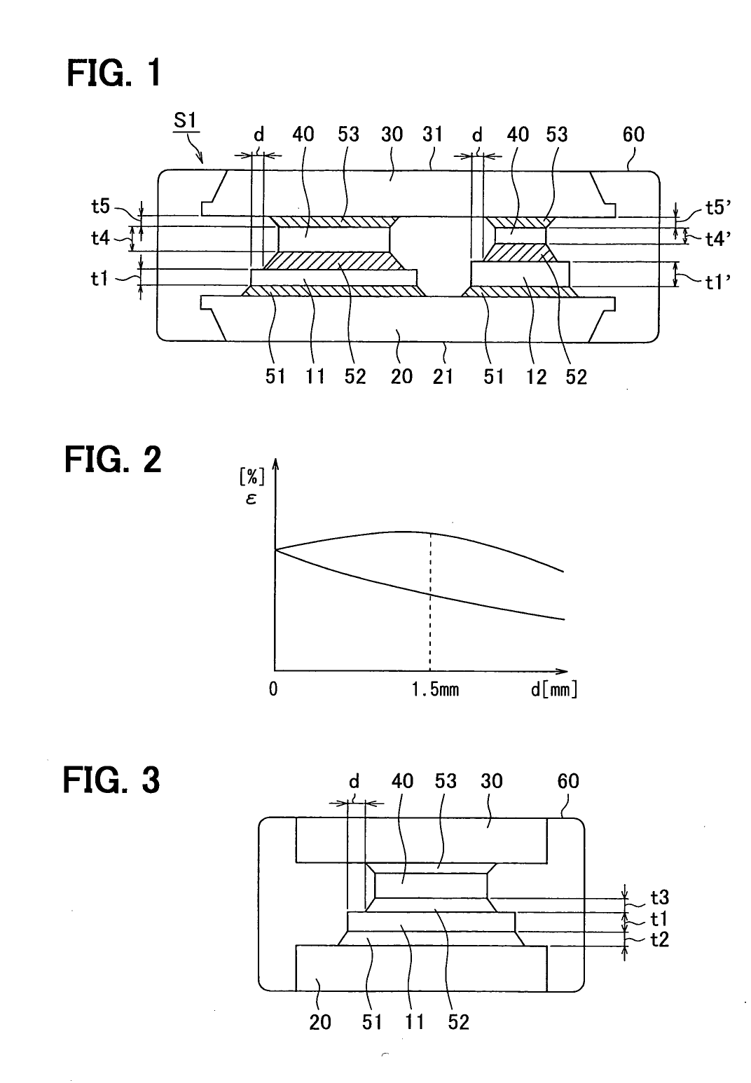

FIG. 1 shows a schematical cross section of the semiconductor device S1 in the present embodiment.

As shown in FIG. 1, the semiconductor device S1 in the present embodiment comprises a first semiconductor chip 11, a second semiconductor ship 12, a lower heat sink 20 as a first metal body, an upper heat sink 30 as a second metal body 30, a heat sink block 40 as a third metal body, solder portions 51, 52, 53 between those chips and metal bodies, and a resin mold 60.

As shown in FIG. 1, the first semiconductor chip 11 and the second semiconductor chip 12 are disposed in parallel on the same plane.

In this structure, the first sides of both semiconductor chips 11, 12 (the lower side in FIG. 1) and the upside of the lower heat sink 20 are connected by the first solder portions 51.

The second sides of both semiconductor chips 11, 12 (the upper side in FIG. 1) and the lower side of the heat sink blocks 40 are connected by the second solder portions 52.

Further, the upper side of the heat sink block 40 and the lower side of the upper heat sink 30 are connected by the third solder portions 53.

In the present embodiment, among the first, second, and third solder portions 51, 52, 53, the first solder portions 51 has the maximum strain measurement. Any typical type of solder can be used for each of the solder portions 51, 52, 53. In this embodiment, Sn (tin) type solder was used.

The above-described structure makes it possible to dissipate heat from the second sides of the first and second semiconductor chip 11, 12 through the second solder portions 52, the heat sink blocks 40, the third solder portions 53 and the upper heat sink 30, and from the first sides of the first and second semiconductor chips 11, 12 through the first solder portions 51 and the lower heat sink 20.

In the semiconductor device S1, outer surfaces of the pair of upper/lower heat sinks 20, 30, are radiating surfaces, that is, the downside in FIG. 1 is a radiating surface 21 in the lower heat sink 20, and the upside in FIG. 1 is a radiating surface 31 in the upper heat sink 30.

The first semiconductor chip 11 is may be a power semiconductor element such as an IGBT (Insulated Gate Bipolar Transistor) and a thyristor. However, the first semiconductor chip 11 is not limited to such elements.

The second semiconductor chip 12 may be an FWD (Free Wheel Diode) and the like. In this embodiment, the first semiconductor chip 11 is an IGBT and the second semiconductor chip 12 is an FWD.

In a concrete form, for example, the first and second semiconductor chip 11, 12 may take shapes of rectangular thin boards.

As shown in FIG. 1, the first semiconductor chip 11 and the second semiconductor chip 12 are different in planar sizes. The first semiconductor chip 11 has a larger planar size than the second semiconductor chip. In this embodiment, the first semiconductor chip 11 has a thinner element thickness than the second semiconductor chip 12.

That is, the thickness t1 of the first semiconductor chip 11 is smaller than the thickness t1′ of the second semiconductor chip 12. The relationship of the thickness t1, t1′ for each of the chips 11, 12, is not necessarily limited to as shown in FIG. 1.

A first side of the first and second semiconductor chips 11, 12 are not used as element disposition surfaces while the second sides are element disposition surfaces for disposing transistors and the like.

On the second sides and the first sides of the first and second semiconductor chips 11, 12 in this embodiment, electrodes not shown in the FIGS. are formed.

The semiconductor device of this embodiment has the electrodes on the first sides of the first and second semiconductor chips 11, 12 electrically connected to the lower heat sink 20 as the first metal body through the first solder portions 51, and the electrodes on the electrodes on the second sides of the first and second semiconductor chips 11, 12 electrically connected to the heat sink blocks 40 through the second solder portion 52.

Further, the heat sink block 40 is connected to the upper heat sink 30 as the second metal body with the side opposite to the semiconductor chips 11, 12 facing side through the third solder portion 53.

The lower heat sink 20, the upper heat sink 30 and the heat sink blocks 40 are, for example, made of a high thermal/electrical conductivity such as copper alloy or aluminum alloy. The heat sink blocks 40 may be made of a typical metal alloy. In this embodiment, each of the metal bodies 20, 30, 40 is made of copper.

The lower heat sink 20 and the upper heat sink 30 are, for example, made in the shape of a rectangular board as a whole. The heat sink block 40, for example, is made in the shape of a rectangular board smaller by a little bit than the semiconductor chips 11, 12.

The heat sink blocks 40 are disposed between the semiconductor chips 11, 12 and the upper heat sink 30, thermally/electrically connecting the chips 11, 12 and the upper heat sink 30, for the purpose of securing a required height for disposing a bonding wire (described later) from the first semiconductor chip 11, and the like.

The lower heat sink 20 and the upper heat sink 30 have a terminal portion protruding from the resin mold 60 (not shown in FIGS.), as an electrode for outer connection. The terminal portion is used for connecting the semiconductor device S1 to the outer circuit parts.

The lower heat sink 20 and the upper heat sink 30 are used respectively as the first metal body and the second metal body, being functional as a radiator as well as an electrode.

A signal terminal, that is made from a lead frame or the like, is disposed on the perimeter of the first semiconductor chip 11, protruding from inside of the resin mold 60 to the outside.

The signal terminal is used as a terminal to be connected to a signal electrode on the surface of the first semiconductor chip 11 or as a reference terminal. The signal terminal and the first semiconductor chip 11 are electrically connected by using a bonding wire (not shown in FIGS.).

Further, the semiconductor device S1 in this embodiment is sealed by a resin mold 60 almost entirely covering the device S1. More particularly, the resin mold 60 seals, as shown in FIG. 1, a space between a pair of heat sinks 20, 30, and a space surrounding the semiconductor chips 11, 12 and the heat sink blocks 40.

The resin mold 60 is made of, for example, a typical mold material such as epoxy resin and the like. In this embodiment, each of the metal bodies 20, 30, 40 is made of copper. In this case, the resin mold 60 is preferably made of the resin with heat expansion coefficient of approximately 11 to 16 ppm/° C.

For molding the heat sink 20, 30, and the like using the resin mold 60, a form block with an upper and lower molds (not shown in FIGS.) is used to conduct a transfer mold method.

The semiconductor device S1 in this embodiment is basically a resin mold type of semiconductor device that includes the first and second semiconductor chips 11, 12 having electrically and thermally connected metal bodies 20, 30, 40 on the second and first sides of the chips by using solder portions 51, 52, 53.

A manufacturing method of the semiconductor device S1 structured in the above described manner is explained with reference to FIG. 1.

First, a soldering process that solders the semiconductor chips 11, 12 and the heat sink blocks 40 to the upper side of the lower heat sink 20 is conducted.

In this case, an Sn type solder foil is, for example, placed on the upper side of the lower heat sink 20 to layer the semiconductor chips 11, 12, and the same solder foil is used on the upper sides of the semiconductor chips 11, 12 to layer the heat sink blocks 40 on each of the chips 11, 12.

The solder is heated above the melting temperature by a heater (reflow device) to be melted, and then is hardened. Next, a process for wire bonding the first semiconductor chip 11 and the signal terminal is conducted.

A soldering process that solders the upper heat sink 30 on each of the heat sink blocks 40 is then conducted. In this case, the upper heat sink 30 is placed with a solder foil on the heat sink blocks 40. The solder foil is melted by a heater and then hardened.

Once each of the melted solder foils is hardened, the hardened solders constitute the first, second, and third solder portions 51, 52, 53.

The solder portions 51, 52, 53 electrically and thermally connect the lower heat sink 20, the semiconductor chips 11, 12, the heat sink blocks 40, and the upper heat sink 30.

Then, a sealing process forms a resin mold in the space between and surrounding the heat sinks 20, 30 and the like by using a form block (not shown in FIGS.). In this manner, the space between and surrounding the heat sinks 20, 30 and the like are filled and sealed with the resin mold 60. This completes the semiconductor device S1.

This semiconductor device S1, in this embodiment, has the lower side of the lower heat sink 20 and the upside of the upper heat sink 30 exposed from the resin mold 60. This structure facilitates heat dissipation efficiency of the heat sinks 20, 30.

In this embodiment, the semiconductor device S1 includes the semiconductor chips 11, 12, the first metal body 20 attached with the first solder portions 51 to the first side of the semiconductor chips 11, 12 as an electrode and a radiator, the second metal body 30 attached with the second solder portions 52 to the second side of the semiconductor chips 11, 12 as an electrode and a radiator, and the resin mold 60 sealing the semiconductor chips 11, 12, the first metal body and the second metal body by encapsulating them. In the semiconductor device S1 having the second side as an element disposition surface, strain measurement caused by heat stress is maximum at the first solder portions 51 among the soldering portions of the semiconductor chips 11, 12 using the solder portions 51, 52, 53.

That is, the strain measurement caused by heat stress is maximum at the first solder portion side 51 on the first side, that is a ‘non element disposition surface,’ of the semiconductor chips 11, 12, and thus the first solder portion 51 will be the first one to be broken among the solder portions when heat stress further concentrates on the portion.

In other words, the soldering portion that is least effective to an increase of thermal resistance will be broken in the first place by heat stress in semiconductor device S1.

Therefore, in this embodiment, an adverse effect of the crack caused by heat stress in the soldering portions can be minimized in the semiconductor device S1 having the first metal body 20 soldered on the first side of the semiconductor chips 11, 12, the second metal body 30 soldered on the second side of the chips 11, 12, and the resin mold 60 covering the device.

As shown in FIG. 1, the first solder 51 covers an entire surface of the first side of the semiconductor chips 11, 12, and the second solder 52 covers a part of the second side of the semiconductor chips 11, 12 with a distance d between the periphery of the solder and the edge of the second side in this embodiment.

The relationship between the distance d (unit: mm) and an equivalent plastic strain value ε of the first and second solder 51, 52 (percentage value) is shown in FIG. 2. The curve in FIG. 2 is derived based on a simulation using a model shown in FIG. 3.

In the model shown in FIG. 3, only the first semiconductor chip 11 is depicted. However, the same tendency is observed in the analysis of the second semiconductor chip 12.

In this analysis, the following conditions, for example, are used. That is, the thickness t1 of the first semiconductor chip 11 made of silicon is 200 μm, the thickness t2, t3 of both of the first and second solder portions 51, 52 made of Sn type solder are 100 μm, the heat expansion coefficient of each of the metal bodies 20, 30, 40 made of copper are 17 ppm/° C., the heat expansion coefficient of resin mold 60 made of epoxy type resin is 14 ppm/° C.

Based on the result shown in FIG. 2, the strain measurement of the second solder portion 52 on the semiconductor chips 11, 12 is smaller at d=‘non zero’ point on the curve, compared to the d=0 point. That is, the distortion of the second solder portion 52 is smaller when the second solder portion 52 partially covers the surface of the semiconductor chips 11, 12 with a certain distance d between the periphery of the second solder portion 52 and the edge of the chips 11, 12, compared to the case when the second solder portion 52 covers the whole surface of the chips 11, 12.

The strain measurement of the second solder portion 52 on the second side of the semiconductor chips 11, 12 by heat stress becomes smaller than the strain measurement of the first solder portion 51 on the first side of the chip 11, 12 by heat stress when the periphery of the second solder portion 52 is disposed with an offset d from the edge of the chips 11, 12, as shown in this embodiment.

That is, the structure with an offset distance d appropriately maximizes the strain measurement of the first solder portion 51 by heat stress in this embodiment.

As shown in FIG. 2, the difference of equivalent plastic strain value ε between the first solder portion 51 and the second solder portion 52 at their peripheries is maximized when the distance d is approximately 1.5 mm. The distance d is preferably set to 1 mm, for example, in this embodiment.

As shown in FIG. 1, the plural semiconductor chips 11, 12 in this embodiment are different in planar sizes and the larger semiconductor chip 11 has a thinner thickness.

According to the inventors, it is clarified that the strain measurement of the solder portions 51, 52 on the semiconductor chip by heat stress becomes larger when the thickness of the semiconductor chip is greater.

Therefore, the thinner the thickness of the semiconductor chip 11 is, especially when the strain measurement tends to be great, the smaller the strain measurement at the soldering portions becomes. That results in an improved strength of the soldering portions, and thus breakage of the portions is prevented.

In this embodiment, as described above, the IGBT element 11 of a large planar size and the FWD element 12 of a planar size smaller than the IGBT element are used as the plural semiconductor elements in the semiconductor device S1. The thickness of the IGBT element 11 is set to, for example, approximately 100 μm, and the thickness of the FWD element 12 is set to 200 μm.

In this embodiment, the thickness t2 of the first solder portion 51 is preferably thinner than the thickness t3 of the second solder portion 52 in the semiconductor device S1. Refer to the FIG. 3 above regarding the relationship between the thickness t2, t3 of the solder portions 51, 52.

According to the inventors, it is clarified that the thinner the thickness of the solder portion is, the larger the strain of the solder portion caused by heat stress becomes.

Therefore, the strain measurement by heat stress of the second solder portion 52 becomes smaller than that of the first solder portion 51 when the thickness of the first solder portion 51 is thinner than that of the second solder portion 52. That is, the strain measurement by heat stress of the first solder portion 51 is appropriately maximized in this manner.

In the above example, the thickness t1 of the IGBT element 11 is, for example, set to approximately 100 μm, and the thickness t1′ of the FWD element 12 is approximately set to 200 μm.

In this embodiment, plural semiconductor chips having different thicknesses t1, t1′ are arranged in parallel on the same plane, and the plural semiconductor chips 11, 12 are disposed between a single pair of lower and upper heat sinks, 20 30.

Therefore, in this embodiment, the plural semiconductor chips 11, 12 of different thickness t1, t1′ are arranged in parallel on the same plane between the single lower heat sink 20 and the opposing single upper heat sink 30 in the semiconductor device S1, and the plural chips 11, 12 are bound by the single pair of upper and lower heat sinks 20, 30.

However, in the structure where the plural semiconductor chips 11, 12 of different thickness t1, t1′ are bound by the single pair of heat sinks 20, 30, the outer surfaces of the pair of heat sinks 20, 30, that is, the radiating surface 21 of the lower heat sink 20 and the radiating surface of the upper heat sink 30 have a tendency to become tilted, and thus a non parallel arrangement of the radiating surfaces 21, 31 may cause a problem.

As shown in FIG. 1, the semiconductor device S1 is, for example, bound by radiating surface 21 of the lower heat sink 20 and the radiating surface 31 of the upper heat sink 30. The radiating surfaces 21, 31 contact cooling members. (not shown in FIGS.) In this case, heat dissipation efficiency deteriorates if the radiating surfaces 21, 31 are not disposed in parallel resulting in the loss of full contact with the cooling members and the like.

When the radiating surface 21 of the lower heat sink 20 and the radiating surface 31 of the upper heat sink 30 are exposed from the resin mold 60, as the semiconductor device S1 shown in FIG. 1, securing the contact between the cooling members and the radiating surfaces 21, 31 is especially important.

For example, the cooling members are thermally connected to the radiating surfaces 21, 31 of the heat sinks 20, 30 through an electrical insulating material. The cooling members can have, for example, an internal coolant passage, and a heat exchange of the heat sinks 20, 30 can be facilitated by a coolant flowing in the coolant passage.

Further, in this case, if the radiating surfaces 21, 31 of the heat sinks 20, 30 are not arranged in parallel, the resin mold 60 is prone to cover the radiating surfaces 21, 31 in the sealing process, because of a gap between the radiating surfaces 21, 31 and the form block, that is, a formation of a resin burr on the radiating surfaces 21, 31 may occur.

The parallel arrangement of the radiating surface 21 of the lower heat sink 20 and the radiating surface 31 of the upper heat sink 30 is secured, for example, by changing the thickness of each of the heat sink blocks 40 on each of the semiconductor chips 11, 12 when the thickness t1, t1′ of each of the plural semiconductor chips 11, 12 are changed.

In concrete, the thickness t4 of the heat sink block 40 on the relatively thin semiconductor chip 11 is made thicker than the thickness t4′ of the heat sink block 40 on the relatively thick second semiconductor chip 12 to achieve the parallel arrangement of the radiating surfaces 21 and 31, as shown in FIG. 1.

The semiconductor device S1 in this embodiment further provides the following characteristics.

For each of the second solder portions 52 on the semiconductor chips 11, 12 of different thickness t1, t1′, a different heat sink block 40 as the third metal body is provided to support the single upper heat sink 30.

Each of the semiconductor chips 11, 12 and the heat sink blocks 40 are attached by each of the second solder portions 52, and each of the heat sink blocks 40 and the single upper heat sink 30 are attached by each of the third solder portions 53.

The thickness t4, t4′ of each of the heat sink blocks 40 is different so that the radiating surface 21 of the single lower heat sink 20 and the radiating surface 31 of the single upper heat sink 30 are disposed in parallel.

In the semiconductor device S1 characterized by the points described above, the heat sink blocks 40, being provided between each of the semiconductor chips 11, 12 and the upper heat sink 30 for adjustment of thickness, absorb the difference between the thickness t1 and t1′ of each of the semiconductor elements 11, 12.

Therefore, the semiconductor device S1 in this embodiment can secure the parallel arrangement of the radiating surface 21 of the lower heat sink 20 and the radiating surface 31 of the upper heat sink 30 in addition to the above-described effect.

The semiconductor device S1 with efficient heat dissipation can thus be provided because of the full contact between the cooling members and each of the radiating surfaces 21, 31 and prevention of resin burr formation on the radiating surfaces 21, 31.

In the example shown in FIG. 1, the parallel arrangement of the radiating surfaces 21, 31 is achieved by changing the thickness t4, t4′ of each of the heat sink blocks 40 on the semiconductor chips 11, 12 when the thickness t1, t1′ of each of the plural semiconductor chips 11, 12 is different. However, the parallel arrangement can also be achieved by changing the thickness t5, t5′ of each of the third solder portions 53 on each of the semiconductor chips 11, 12.

In concrete, the parallel arrangement of the radiating surfaces 21, 31 can be achieved by setting the thickness t5 of the third solder portion 53 on the relatively thin first semiconductor chips 11 thicker than the thickness t5′ of the third solder portion 53 on the relatively thick second semiconductor chip 12, on condition that the heat sink blocks 40 on each of the semiconductor chips 11, 12 have the same thickness t4, t4′.

The semiconductor device S1 in this embodiment has the following characteristics when the thickness t5, t5′ of each of the third solder portions 53 is changed.

For each of the second solder portions 52 on the semiconductor chips 11, 12 of different thickness t1, t1′, a different heat sink block 40 as the third metal body is provided to support the single upper heat sink 30.

Each of the semiconductor chips 11, 12 and the heat sink blocks 40 are attached by the second solder portions 52, and each of the heat sink blocks 40 and the single upper heat sink 30 are attached by the third solder portions 53.

The thickness t5, t5′ of each of the heat sink blocks 40 is different so that the radiating surface 21 of the single lower heat sink 20 and the radiating surface 31 of the single upper heat sink 30 are disposed in parallel.

In the semiconductor device S1 characterized by the points described above, the heat sink blocks 40 are disposed between each of the semiconductor chips 11, 12 and the upper heat sink 30, and the third solder portions 53, being provided on each of the semiconductor chips 11, 12 for adjustment of thickness, absorb the difference of thickness t1 and t1′ of the semiconductor chips 11, 12.

Therefore, a semiconductor device S1 having efficient heat dissipation can be provided, because the full contact between the cooling members and each of the radiating surfaces 21, 31, and prevention of resin burr formation on the radiating surfaces 21, 31 are achieved by securing the parallel arrangement of the radiating surfaces 21, 31.

### Modified Embodiment

In the example shown in FIG. 1, the parallel arrangement of the radiating surfaces 21, 31 is achieved by changing the thickness t4, t4′ of each of the heat sink blocks 40, or the thickness t5, t5′ of each of the third solder portions 53 on each of the semiconductor chips 11, 12, when the thickness t1, t1′ of each of the plural semiconductor chips 11, 12 are different.

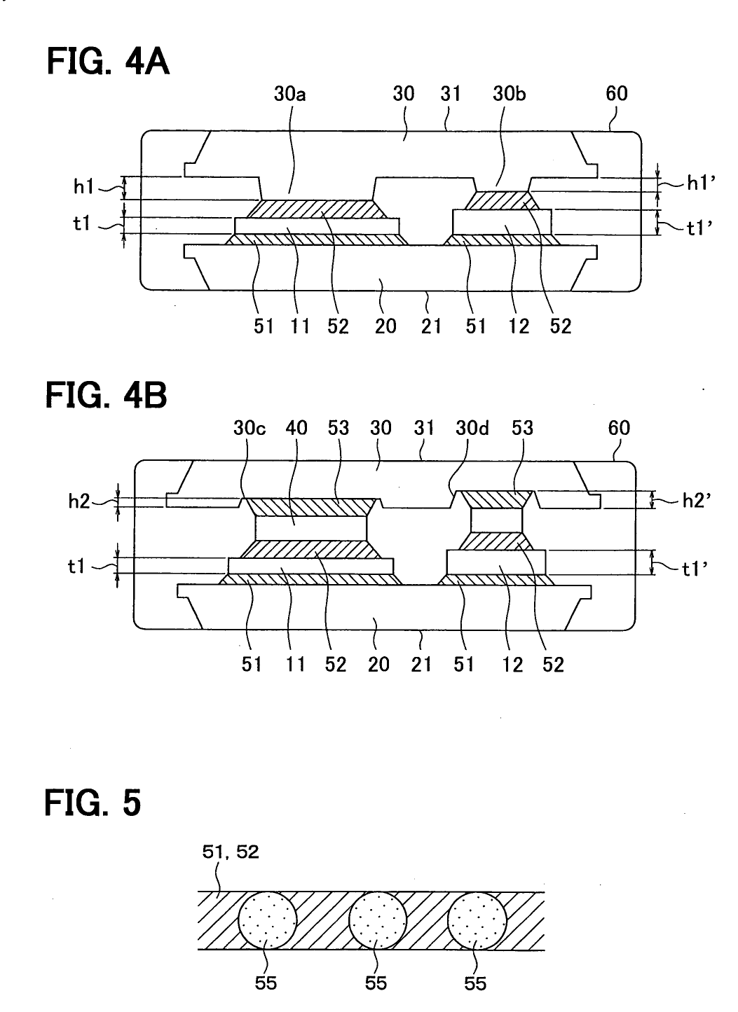

In this modified embodiment, a different method is devised to achieve the parallel arrangement. FIG. 4A and FIG. 4B show schematic cross sections of the first modified embodiment and the second modified embodiment respectively.

The semiconductor devices in FIG. 4A and FIG. 4B differ in the method to achieve the parallel arrangement of the radiating surfaces 21, 31, with the same structure in the remaining portion.

In the semiconductor devices in FIG. 4A and FIG. 4B, plural semiconductor chips 11, 12 of different thickness t1, t1′ are disposed on the same plane between the single lower heat sink 20 and the opposing single upper heat sink 30. The plural semiconductor chips 11, 12 are bound by the single lower heat sink 20 and the opposing single upper heat sink 30. The radiating surfaces 21, 31 are exposed from the resin mold 60.

In the semiconductor device in the modified embodiment, the upper heat sink 30 has the concave/convex portion on the semiconductor chips 11, 12 side, and this structure achieves the parallel arrangement of the radiating surface 21 of the single lower heat sink 20 and the radiating surface 31 of the single upper heat sink 30, as shown in FIG. 4A, and FIG. 4B.

In the semiconductor device shown in FIG. 4A, the upper heat sink 30 includes convex portions 30a, 30b of different height h1, h1′ disposed on the sides of semiconductor chips 11, 12 that face the upper heat sink 30.

That is, the relatively high convex portion 30a of height h1 is disposed to be contacted against the relatively thin IGBT element 11 of thickness t1 through the second solder 52, and the relatively low convex portion 30b of height h1′ is disposed to be contacted against the relatively thick FWD element 12 of thickness t1′ through the second solder 52.

In the semiconductor device shown in FIG. 4B, concave portions 30c, 30d of different depth h2, h2′ are disposed on the side of the semiconductor chips 11, 12 that faces the single upper heat sink 30.

That is, the relatively shallow concave portion 30c of depth h2 is disposed to be contacted against the relatively thin IGBT element 11 of thickness t1 through the heat sink block 40, the second solder portion 52 and the third solder portion 53, and the relatively deep concave portion 30d of depth h2′ is disposed to be contacted against the relatively thick FWD element 12 of thickness t1′ through the heat sink block 40, the second solder portion 52 and the third solder portion 53.

In this manner, the semiconductor device in this modified embodiment absorbs the difference of thickness t1, t1′ by disposing concave/convex portions on the upper heat sink 30 for each of the semiconductor chips 11, 12 for adjustment of thickness.

Therefore, the semiconductor devices shown in FIG. 4A and FIG. 4B can achieve the parallel arrangement of the radiating surfaces 21, 31 in addition to the above-described objective of the present invention. In this manner, the semiconductor device having efficient heat dissipation can be provided, because the full contact between the cooling members and each of the radiating surfaces 21, 31, and prevention of resin burr formation on the radiating surfaces 21, 31 are achieved.

The semiconductor devices shown in FIG. 4A and FIG. 4B can also secure the parallel arrangement of the radiating surfaces 21, 31 with a method different from changing the thickness of the heat sink block 40 or the third solder 53.

Further, in FIG. 4A, there is no heat sink block 40 and accompanying third solder portion 53. However, these components may be used in the structure. Furthermore, in FIG. 4B, the heat sink block 40 and accompanying third solder portion 53 may be omitted.

In FIG. 5, a schematic cross section of the first solder portion 51 and the second solder portion 52 is shown as the third modified embodiment.

The semiconductor device shown in the preceding FIGS. may have the first solder portions 51 on the second side and the second solder portions 52 on the reverse of each of the semiconductor chips 11, 12, the solder portions containing a metal powder 55 for defining the height t2, t3 (shown in FIG. 3) of the solder portion.

As the metal powder 55, a grain of Ni of diameter of several dozen to hundred μm may be used. The metal powder of this kind is prepared in a form of solder foil or in a ribbon.

By using the metal powder, the thickness of the first solder portion 51 and the second solder portions 52 can be controlled with ease, and thus the parallel arrangement of the radiating surface 21 of the lower heat sink 20 and the radiating surface 31 of the upper heat sink 30 can preferably achieved.

In the semiconductor device S1 shown in FIG. 1, the relatively thin IGBT element 11 and the FWD element 12 thicker than the IGBT element 11 are used as the plural semiconductor chips 11, 12 of thickness t1, t1′. However, different type of element may be used as the semiconductor chips 11, 12. Further, the number of the semiconductor chips may be three or more.

### Other Embodiment

In the above embodiments, the semiconductor device included a plurality of semiconductor elements 11, 12. However, the semiconductor device may include only a single semiconductor element.

In the above description, the heat sink blocks 40, being disposed between the semiconductor chips 11, 12 and the upper heat sink 30, is used for securing a space between the first semiconductor chip 11 and the upper heat sink 30, or securing the parallel arrangement of the radiating surfaces 21, 31 of the upper and lower heat sinks 20, 30. However, the heat sink blocks 40 can be omissible, if it is not necessary, in the preceding embodiments.

Therefore, the present disclosure concerns a semiconductor device including semiconductor elements 11, 12, a first metal body 20 attached to the first side of the semiconductor elements 11, 12 with a first solder portion 51, a second metal body 30 attached to the second side opposite to the first side of the semiconductor elements 11, 12 with the second solder portion 52, and the resin mold 60 sealing the semiconductor elements 11, 12, the first metal body and the second metal body by encapsulating them, with the strain measurement of heat stress being maximum at the first solder portion 51 among soldering portions. The design of the other portion may suitably be changed.

1. A semiconductor device comprising:
a semiconductor element;
a first metal body attached to a first side of the semiconductor element by a first solder portion, wherein the first metal body serves as an electrode and a radiator;
a second metal body attached to a second side of the semiconductor element by a second solder portion, wherein the second metal body also serves as an electrode and a radiator, wherein the second side is opposite to the first side of the semiconductor element and serves as an element disposition surface; and
a resin mold sealing the semiconductor element, the first metal body and the second metal body by encapsulating them,
wherein the first solder portion has maximum strain measurement caused by heat stress, among the soldering portions of the semiconductor element.

2. The semiconductor device of claim 1,
wherein the first solder portion covers an entire surface of the first side of the semiconductor element, and
wherein the second solder portion covers a part of the second side of the semiconductor element with a predetermined distance between an outer periphery of the second solder portion and an edge of the second side of the semiconductor element.

3. The semiconductor device of claim 1, wherein the semiconductor element further comprises first and second semiconductor elements, wherein each of the first and second semiconductor elements has different planar sizes, wherein the semiconductor element having a larger planar size has a thinner thickness than the other semiconductor element.

4. The semiconductor device of claim 3, wherein the semiconductor element of larger planar size is an IGBT element and the semiconductor element of smaller planar size is an FWD element.

5. The semiconductor device of any one of claims 1, wherein the first solder portion is thinner than the second solder portion.

6. The semiconductor device of claim 3, wherein both of the first and second semiconductor elements of different thickness are disposed on the same plane between the first metal body and the second metal body opposed to the first metal body.

7. The semiconductor device of claim 6, wherein a radiating surface of the first metal body and a radiating surface of the second metal body are exposed from the resin mold.

8. The semiconductor device of claim 6,
wherein, for each of the first and second semiconductor elements, a different third metal body is disposed between the second solder portion on the semiconductor elements and the second metal body,
wherein each of the first and second semiconductor elements and the third metal bodies are attached by the second solder portion,
wherein each of the third metal bodies and the second metal body are attached by the third solder portions,
wherein each of the third metal bodies has a different thickness so that the radiating surface of the first metal body and the radiating surface of the second metal body are disposed in parallel.

9. The semiconductor device of claim 6,
wherein a different third metal body is disposed between the second solder portions on the semiconductor elements and the second metal body for each of the semiconductor elements,
wherein each of the semiconductor elements and the third metal bodies are attached by the second solder portions,
wherein each of the third metal bodies and the second metal body are attached by the third solder portions,
wherein each of the third solder has a different thickness so that the radiating surface of the first metal body and the radiating surface of the second metal body are disposed in parallel.

10. The semiconductor device of claim 6,
wherein the second metal body has a concave or convex portions on a side facing towards the semiconductor elements, and
wherein the concave or convex portions permit the radiating surface of the first metal body and the radiating surface of the second metal body in parallel.

11. The semiconductor device of claim 6, wherein the first solder portion and the second solder portion include a metal powder for defining a height of the solder.

12. The semiconductor device of claim 6, wherein the semiconductor element of relatively thin thickness is an IGBT element and the thicker semiconductor element is an IGBT element.
